(19) United States
(12) Patent Application Publication
(10) Pub. No.: US 2023/0331627 A1
(43) Pub. Date: Oct. 19, 2023

(54) LAMINATE, LAMINATE WITH MEMBER FOR ELECTRONIC DEVICE, AND METHOD FOR MANUFACTURING ELECTRONIC DEVICE

(71) Applicant: AGC Inc., Tokyo (JP)

(72) Inventors: Kazuo YAMADA, Tokyo (JP); Shuma KAWASAKI, Tokyo (JP)

(73) Assignee: AGC Inc., Tokyo (JP)

(21) Appl. No.: 18/299,742

(22) Filed: Apr. 13, 2023

(30) Foreign Application Priority Data
Apr. 15, 2022 (JP) 2022-067597

(51) Int. Cl. C03C 17/34; C23C 16/34; C23C 16/50; C23C 16/40; C23C 16/24; C23C 16/02

(52) U.S. Cl. CPC C03C 17/3435; C23C 16/345; C23C 16/50; C23C 16/401; C23C 16/24; C23C 16/0272; C03C 2218/153; C03C 2217/213; C03C 2217/281

(57) ABSTRACT

The present invention relates to a laminate including: a support substrate; and a laminated portion, including an adhesion layer, a polyimide layer, and an inorganic layer, disposed on the support substrate, in which, when the laminate is observed from a normal direction of its surface, an outer edge of the polyimide layer is located outside an outer edge of the adhesion layer, and an outer edge of the inorganic layer coincides with the outer edge of the adhesion layer; the outer edge of the inorganic layer is located inside the outer edge of the adhesion layer; or a part of the outer edge of the inorganic layer coincides with a part of the outer edge of the adhesion layer and a remaining part of the outer edge of the inorganic layer is located inside the outer edge of the adhesion layer.

### CROSS-REFERENCE TO RELATED APPLICATIONS

This application is based on and claims priority under 35 USC 119 from Japanese Patent Application No. 2022-067597 filed on Apr. 15, 2022, the entire content of which is incorporated herein by reference.

### TECHNICAL FIELD

The present invention relates to a laminate, a laminate with a member for electronic device, and a method for manufacturing an electronic device.

### BACKGROUND ART

A reduction in thickness and weight of an electronic device such as a solar cell (PV), a liquid crystal panel (LCD), an organic EL panel (OLED), and a receiving sensor panel that senses electromagnetic waves, X-rays, ultraviolet rays, visible light, infrared rays, and the like is advanced. Accordingly, thinning of a substrate such as a polyimide substrate used for an electronic device is also advanced. If a strength of the substrate is insufficient due to thinning, a handling property of the substrate may be lowered, and a problem may occur in a process of forming an electronic device member on the substrate or the like.

Accordingly, recently, in order to improve the handling property of the substrate, a technique of using a laminate in which a polyimide substrate is disposed on a support substrate has been proposed (Patent Literature 1). More specifically, Patent Literature 1 discloses that a thermosetting resin composition cured body layer is coated with a polyimide varnish to form a resin varnish cured film (corresponding to a polyimide layer), and a precision element can be disposed on the resin varnish cured film.

That is, Patent Literature 1 discloses a technique of forming a polyimide layer using a polyimide varnish and disposing a precision element (corresponding to an electronic device) on the polyimide layer.

### CITATION LIST

### Patent Literature

Patent Literature 1: JP2018-193544A

### SUMMARY OF INVENTION

### Technical Problem

At the time of disposing an electronic device on a polyimide layer, an attempt has been made to dispose an inorganic layer on the polyimide layer and then dispose the electronic device on the inorganic layer. Since the inorganic layer has an excellent gas barrier property, it is expected to maintain and improve a performance of the electronic device.

The present inventors have studied characteristics of a laminate obtained by disposing a polyimide layer on an adhesion layer which is a thermosetting resin composition cured body layer by using the technique described in Patent Literature 1, and further disposing an inorganic layer on the polyimide layer, and have found that when the laminate is subjected to a heat treatment (particularly, a heat treatment at a temperature of about 380° C.), occurrence of foaming and cracking in the polyimide layer is sometimes observed. If such foaming or cracking occurs, process contamination may be caused in a process of manufacturing an electronic device, and a performance of the electronic device may be deteriorated.

An object of the present invention is to provide a laminate including a support substrate, an adhesion layer, a polyimide layer, and an inorganic layer, in which occurrence of foaming and cracking in the polyimide layer is prevented when a heat treatment is performed.

Another object of the present invention is to provide a laminate with a member for electronic device and a method for manufacturing an electronic device.

### Solution to Problem

As a result of intensive studies, the present inventors have found that the above problems can be solved by the following configuration.
(1) A laminate including:
   a support substrate; and
   a laminated portion disposed on at least a partial region of the support substrate, in which
   the laminated portion includes an adhesion layer, a polyimide layer, and an inorganic layer in this order from a support substrate side, and
   when the laminate is observed from a normal direction of a surface of the laminate,
   an outer edge of the polyimide layer is located outside an outer edge of the adhesion layer, and
   an outer edge of the inorganic layer coincides with the outer edge of the adhesion layer; the outer edge of the inorganic layer is located inside the outer edge of the adhesion layer; or a part of the outer edge of the inorganic layer coincides with a part of the outer edge of the adhesion layer and a remaining part of the outer edge of the inorganic layer is located inside the outer edge of the adhesion layer.
(2) The laminate according to (1), in which the adhesion layer is a silicone resin layer.
(3) The laminate according to (1) or (2), in which the inorganic layer includes a nitride including Si or an oxide including Si.
(4) The laminate according to any one of (1) to (3), in which two or more of the laminated portions are disposed on the support substrate.
(5) The laminate according to any one of (1) to (4), in which the support substrate is a glass substrate.
(6) A laminate with a member for electronic device, including:
   the laminate according to any one of (1) to (5); and
   a member for electronic device disposed on the inorganic layer of the laminate.
(7) A method for manufacturing an electronic device, the method including:
   a member forming step of forming a member for electronic device on the inorganic layer of the laminate according to any one of (1) to (5) to obtain a laminate with a member for electronic device; and
   a separation step of obtaining an electronic device including the polyimide layer, the inorganic layer, and the member for electronic device from the laminate with a member for electronic device.

### Advantageous Effects of Invention

According to the present invention, it is possible to provide a laminate including a support substrate, an adhesion layer, a polyimide layer, and an inorganic layer, in which occurrence of foaming and cracking in the polyimide layer is prevented when a heat treatment is performed.

According to the present invention, it is possible to provide a laminate with a member for electronic device and a method for manufacturing an electronic device.

### BRIEF DESCRIPTION OF DRAWINGS

FIG. 1 is a cross-sectional view schematically showing a laminate in which foaming and cracking occur in a polyimide layer.

FIG. 2 is a cross-sectional view schematically showing a first embodiment of a laminate of the present invention.

FIG. 3 is a plan view of the first embodiment of the laminate shown in FIG. 2.

FIG. 4 is a cross-sectional view schematically showing a second embodiment of the laminate of the present invention.

FIG. 5 is a plan view of the second embodiment of the laminate shown in FIG. 4.

FIG. 6 is a cross-sectional view schematically showing a third embodiment of the laminate of the present invention.

FIG. 7 is a plan view of the third embodiment of the laminate shown in FIG. 6.

FIG. 8 is a cross-sectional view schematically showing another embodiment of the laminate of the present invention.

FIG. 9 is a view illustrating a member forming step.

FIG. 10 is a view illustrating a cutting step.

FIG. 11 is a view illustrating a separation step.

FIG. 12 is a cross-sectional view schematically showing a laminate of Examples 11 and 12.

FIG. 13 is a cross-sectional view schematically showing a laminate of Examples 13 and 14.

FIG. 14 is a cross-sectional view schematically showing a laminate of Examples 15 and 16.

### DESCRIPTION OF EMBODIMENTS

Hereinafter, embodiments of the present invention will be described with reference to the drawings. However, the following embodiments are exemplifications for describing the present invention, and the present invention is not limited to the following embodiments. Various modifications and substitutions can be made in the following embodiments without departing from the scope of the present invention.

A numerical range represented using “to” means a range including numerical values described before and after “to” as a lower limit value and an upper limit value.

A feature of a laminate of the present invention is that arrangement positions of an adhesion layer, a polyimide layer, and an inorganic layer are adjusted.

The present inventors have studied a cause of occurrence of foaming and cracking in the polyimide layer, and have found that neither foaming nor cracking occurs in the polyimide layer located on the adhesion layer, but foaming and cracking occur in the polyimide layer that is not located on the adhesion layer and is covered with the inorganic layer.

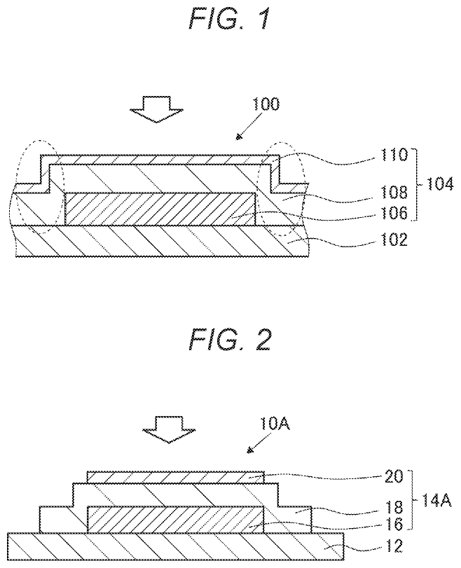

More specifically, a laminate 100 shown in FIG. 1 includes a support substrate 102 and a laminated portion 104, and the laminated portion 104 includes an adhesion layer 106, a polyimide layer 108, and an inorganic layer 110 arranged in this order from a support substrate 102 side. In the laminate 100, the polyimide layer 108 covers the adhesion layer 106, and when the laminate 100 is observed from a normal direction (a white arrow direction in FIG. 1, which corresponds to a lamination direction of each member of the laminate) of a surface of the laminate 100, an outer edge of the polyimide layer 108 is located outside an outer edge of the adhesion layer 106. The inorganic layer 110 covers an entire surface of the polyimide layer 108. When such a laminate 100 was subjected to a heat treatment, foaming and cracking occurred in regions of the polyimide layer 108 located on the support substrate 102 and covered with the inorganic layer 110, which are surrounded with respective broken lines. On the other hand, neither foaming nor cracking was observed in a region of the polyimide layer 108 located on the adhesion layer 106. Although details of the reason for occurrence of the above phenomenon are unclear, it is considered that heat resistance of the polyimide layer 108 is improved with the presence of the adhesion layer 106, or that moisture contained in the polyimide layer 108 is absorbed by the adhesion layer 106, and foaming and cracking are prevented, or the like.

As described above, the foaming and the cracking are observed in the regions of the polyimide layer 108 that are not located on the adhesion layer 106 and are covered with the inorganic layer 110.

Therefore, in the present invention, as shown in FIG. 2 and the like to be described later, it is found that occurrence of the above problem can be prevented by adjusting an arrangement region of the inorganic layer with respect to the adhesion layer. Particularly, an arrangement region of the inorganic layer on the polyimide layer is adjusted such that a volatile component such as moisture contained in the polyimide layer can volatilize out of the laminate when the laminate is subjected to a heat treatment.

### <Laminate>

FIG. 2 is a cross-sectional view schematically showing a first embodiment of the laminate of the present invention.

A laminate 10A includes a support substrate 12, and a laminated portion 14A disposed on a partial region of the support substrate 12. In the laminated portion 14A, an adhesion layer 16, a polyimide layer 18, and an inorganic layer 20 are arranged in this order from a support substrate 12 side.

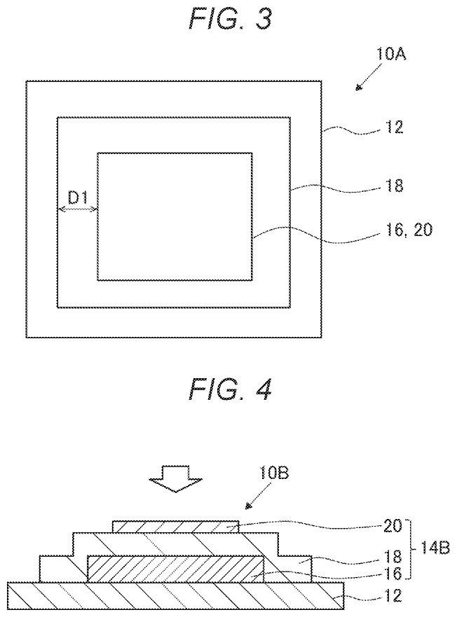

FIG. 3 is a plan view of the laminate 10A when the laminate 10A is observed from a normal direction (a white arrow direction in FIG. 2, which corresponds to a lamination direction of each member of the laminate, and also corresponds to a thickness direction of the laminate) of a surface of the laminate 10A (when the laminate 10A is viewed in a plan view from the normal direction of the surface of the laminate 10A). When the laminate 10A is observed from the normal direction (the white arrow direction in FIG. 2) of the surface of the laminate 10A, as shown in FIG. 3, in the laminate 10A, an outer edge of the polyimide layer 18 is located outside an outer edge of the adhesion layer 16, and an outer edge of the inorganic layer 20 coincides with the outer edge of the adhesion layer 16. That is, as shown in FIG. 3, the outer edge of the polyimide layer 18 is located outside a region surrounded by the outer edge of the adhesion layer 16, and a position of the outer edge of the inorganic layer 20 and a position of the outer edge of the adhesion layer 16 overlap each other.

In such a laminate 10A, even after a heat treatment is performed, occurrence of foaming and cracking in the polyimide layer 18 is prevented.

In the first embodiment, it is sufficient that the outer edge of the polyimide layer 18 is located outside the outer edge of the adhesion layer 16, and the outer edge of the polyimide layer 18 is preferably located 1 mm or more away from the outer edge of the adhesion layer 16, and more preferably located 3 mm to 10 mm away from the outer edge of the adhesion layer 16. That is, as shown in FIG. 3, when the laminate 10A is observed from the normal direction of the surface of the laminate 10A, a distance D1 from a point on the outer edge of the adhesion layer 16 to a position of the outer edge of the polyimide layer 18 at a closest position is preferably 1 mm or more, and more preferably 3 mm to 10 mm.

In FIG. 3, the polyimide layer 18 is disposed on a partial region of the support substrate 12, but may be disposed on an entire surface of the support substrate 12.

As shown in FIG. 3, the adhesion layer 16, the polyimide layer 18, and the inorganic layer 20 have a square shape, but shapes thereof are not particularly limited as long as the above relationship is satisfied.

When the laminate 10A is observed from the normal direction of the surface of the laminate 10A, the shapes of the adhesion layer 16 and the polyimide layer 18 are preferably similar figures.

When the laminate 10A is observed from the normal direction of the surface of the laminate 10A, a center of gravity of the adhesion layer 16, a center of gravity of the polyimide layer 18, and a center of gravity of the inorganic layer 20 are consistent with each other, but the present invention is not limited to this mode, and in the laminate of the present invention, the centers of gravity of the respective layers may not be consistent with each other.

The polyimide layer 18 may be either colorless or colored, and when the polyimide layer 18 is colored and the position of the outer edge of the adhesion layer 16 covered with the polyimide layer 18 cannot be confirmed through the polyimide layer 18, the position of the outer edge of the adhesion layer 16 may be confirmed by cutting the laminate 10A and observing a cross section thereof. In addition to cutting the laminate 10A and observing the cross section thereof, the position of the outer edge of the adhesion layer 16 may be confirmed by scraping the polyimide layer 18 as necessary.

The inorganic layer 20 may be either colorless or colored, and when the inorganic layer 20 is colored and the position of the outer edge of the adhesion layer 16 and/or the position of the outer edge of the polyimide layer 18 cannot be confirmed due to the presence of the inorganic layer 20, the positions of the outer edges of the adhesion layer 16 and the polyimide layer 18 may be confirmed by cutting the laminate 10A and observing a cross section thereof. In addition to cutting the laminate 10A and observing the cross section thereof, the positions of the outer edges of the adhesion layer 16 and the polyimide layer 18 may be confirmed by scraping the inorganic layer 20 as necessary.

When the laminate 10A is observed from the normal direction of the surface of the laminate 10A, a ratio of an area of the adhesion layer 16 to an area of the support substrate 12 is preferably 80% to 99%, and more preferably 85% to 98%. When the laminate 10A is observed from the normal direction of the surface of the laminate 10A, a ratio of an area of the polyimide layer 18 to the area of the support substrate 12 is preferably 90% to 100%, and more preferably 95% to 100%.

FIG. 4 is a cross-sectional view schematically showing a second embodiment of the laminate of the present invention.

A laminate 10B includes the support substrate 12, and a laminated portion 14B disposed on a partial region of the support substrate 12. In the laminated portion 14B, the adhesion layer 16, the polyimide layer 18, and the inorganic layer 20 are arranged in this order from a support substrate 12 side.

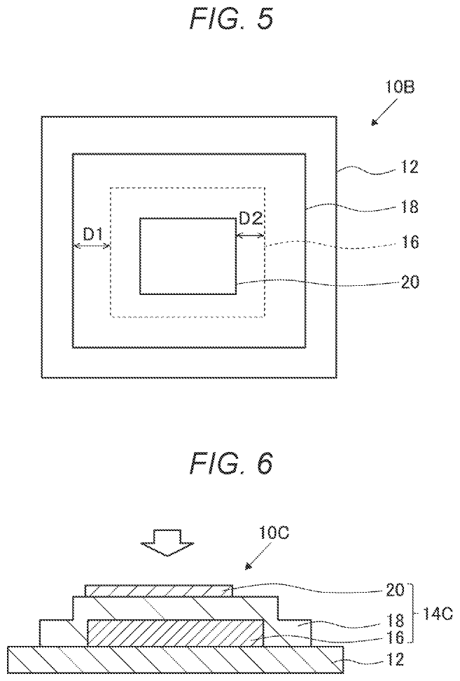

FIG. 5 is a plan view of the laminate 10B when the laminate 10B is observed from a normal direction (a white arrow direction in FIG. 4) of a surface of the laminate 10B. As shown in FIG. 5, in the laminate 10B, when the laminate 10B is observed from the normal direction of the surface of the laminate 10B, an outer edge of the polyimide layer 18 is located outside an outer edge of the adhesion layer 16, and an outer edge of the inorganic layer 20 is located inside the outer edge of the adhesion layer 16.

The first embodiment shown in FIG. 2 and the second embodiment shown in FIG. 4 have the same configuration except for an arrangement position of the inorganic layer. That is, a positional relationship between the outer edge of the polyimide layer 18 and the outer edge of the adhesion layer 16 in the second embodiment is the same as a positional relationship between the outer edge of the polyimide layer 18 and the outer edge of the adhesion layer 16 in the first embodiment, and a suitable range of a distance of D1 shown in FIG. 5 is the same as a suitable range of a distance of D1 shown in FIG. 3. Suitable ranges of a ratio of an area of the adhesion layer 16 to an area of the support substrate 12 and a ratio of an area of the polyimide layer 18 to the area of the support substrate 12 in the second embodiment are the same as suitable ranges of ratios described in the first embodiment, respectively.

In the laminate 10B shown in FIG. 4, the outer edge of the inorganic layer 20 is located inside the outer edge of the adhesion layer 16. That is, as shown in FIG. 5, the outer edge of the inorganic layer 20 is located inside a region surrounded by the outer edge of the adhesion layer 16 without overlapping with the outer edge of the adhesion layer 16.

When the laminate 10B is observed from the normal direction of the surface of the laminate 10B, a center of gravity of the adhesion layer 16, a center of gravity of the polyimide layer 18, and a center of gravity of the inorganic layer 20 are consistent with each other, but the present invention is not limited to this mode, and in the laminate of the present invention, the centers of gravity of the respective layers may not be consistent with each other.

In the second embodiment, it is sufficient that the outer edge of the inorganic layer is located inside the outer edge of the adhesion layer 16, and the outer edge of the inorganic layer 20 is preferably located 1 mm or more away from the outer edge of the adhesion layer 16, and more preferably located 2 mm to 10 mm away from the outer edge of the adhesion layer 16. That is, as shown in FIG. 5, when the laminate 10B is observed from the normal direction of the surface of the laminate 10B, a distance D2 from a point on the outer edge of inorganic layer 20 to a position of the outer edge of the adhesion layer 16 at a closest position is preferably 1 mm or more, and more preferably 2 mm to 10 mm.

When the laminate 10B is observed from the normal direction of the surface of the laminate 10B, a ratio of an area of the inorganic layer 20 to the area of the adhesion layer 16 is preferably 90% or more and less than 100%, and more preferably 95% or more and less than 100%.

As shown in FIG. 5, the adhesion layer 16, the polyimide layer 18, and the inorganic layer 20 have a square shape, but shapes thereof are not particularly limited as long as the above relationship is satisfied.

When the laminate 10B is observed from the normal direction of the surface of the laminate 10B, the shapes of the adhesion layer 16, the polyimide layer 18, and the inorganic layer 20 are preferably similar figures.

FIG. 6 is a cross-sectional view schematically showing a third embodiment of the laminate of the present invention.

A laminate 10C includes the support substrate 12, and a laminated portion 14C disposed on a partial region of the support substrate 12. In the laminated portion 14C, the adhesion layer 16, the polyimide layer 18, and the inorganic layer 20 are arranged in this order from a support substrate 12 side.

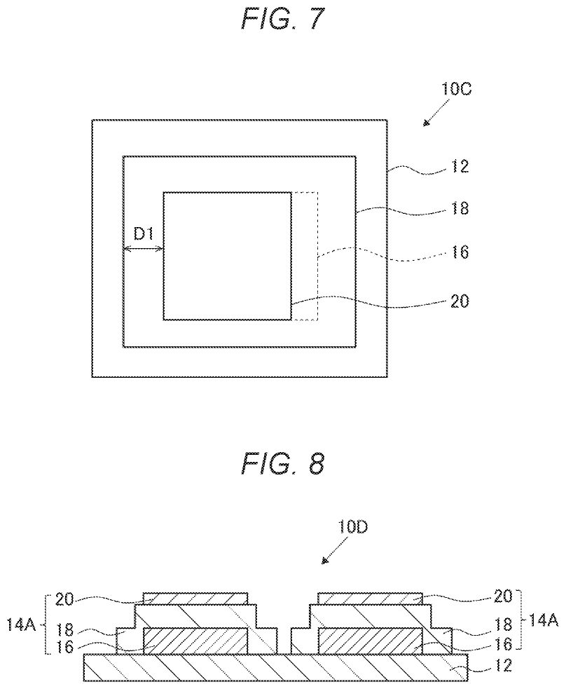

FIG. 7 is a plan view of the laminate 10C when the laminate 10C is observed from a normal direction (a white arrow direction in FIG. 6) of a surface of the laminate 10C. As shown in FIG. 7, in the laminate 10C, when the laminate 10C is observed from the normal direction of the surface of the laminate 10C, an outer edge of the polyimide layer 18 is located outside an outer edge of the adhesion layer 16, a part of an outer edge of the inorganic layer coincides with a part of the outer edge of the adhesion layer 16, and a remaining part of the outer edge of the inorganic layer 20 is located inside the outer edge of the adhesion layer 16.

The first embodiment shown in FIG. 2 and the third embodiment shown in FIG. 6 have the same configuration except for an arrangement position of the inorganic layer. That is, a positional relationship between the outer edge of the polyimide layer 18 and the outer edge of the adhesion layer 16 in the third embodiment is the same as the positional relationship between the outer edge of the polyimide layer 18 and the outer edge of the adhesion layer 16 in the first embodiment, and a suitable range of a distance of D1 shown in FIG. 7 is the same as the suitable range of the distance of D1 shown in FIG. 3. Suitable ranges of a ratio of an area of the adhesion layer 16 to an area of the support substrate 12 and a ratio of an area of the polyimide layer 18 to the area of the support substrate 12 in the third embodiment are the same as the suitable ranges of the ratios described in the first embodiment, respectively.

In the laminate 10C shown in FIG. 6, the part of the outer edge of the inorganic layer 20 coincides with the outer edge of the adhesion layer 16, and the remaining part of the outer edge of the inorganic layer 20 is located inside the outer edge of the adhesion layer 16. That is, as shown in FIG. 7, the part of the outer edge of the inorganic layer 20 and the part of the outer edge of the adhesion layer 16 overlap each other, and the remaining part of the outer edge of the inorganic layer 20 is located inside a region surrounded by the outer edge of the adhesion layer 16 without overlapping with the outer edge of the adhesion layer 16. In FIG. 7, three sides of four sides constituting the outer edge of the square-shaped inorganic layer 20 overlap the part of the outer edge of the adhesion layer 16, and one remaining side of the four sides constituting the outer edge of the inorganic layer 20 is located inside the region surrounded by the outer edge of the adhesion layer 16.

A range in which the outer edge of the inorganic layer 20 and the outer edge of the adhesion layer 16 coincides with each other is not particularly limited.

When the laminate 10C is observed from the normal direction of the surface of the laminate 10C, a ratio of an area of the inorganic layer 20 to the area of the adhesion layer 16 is preferably 90% or more and less than 100%, and more preferably 95% or more and less than 100%.

Although FIGS. 2 to 7 show a mode in which one laminated portion is disposed on a support substrate, two or more of the laminated portions may be arranged on a support substrate. For example, as shown in FIG. 8, a laminate 10D includes the support substrate 12, and two laminated portions 14A arranged on a partial region of the support substrate 12. The laminated portion 14A has a configuration described in the first embodiment.

When the laminate includes a plurality of laminated portions, the number of laminated portions is not particularly limited, and is preferably 2 to 16, and more preferably 2 to 4.

Hereinafter, each of members constituting the laminate will be described in detail.

### (Support Substrate)

The support substrate is a member that supports and reinforces the laminated portion.

Examples of the support substrate include a glass substrate, a plastic substrate, and a metal plate (for example, a SUS plate). Among these, a glass substrate is preferred.

As a glass constituting the glass substrate, an alkali-free borosilicate glass, a borosilicate glass, a soda lime glass, a high silica glass, and other oxide-based glasses containing silicon oxide as a main component are preferred. As the oxide-based glass, a glass having a silicon oxide content of 40 mass % to 90 mass % in terms of oxide is preferred.

More specifically, examples of the glass substrate include a glass substrate made of an alkali-free borosilicate glass (trade name “AN 100” manufactured by AGC Inc.).

The glass substrate is usually manufactured by melting a glass raw materials and molding molten glass into a plate shape. Such a molding method may be a general method, and examples thereof include a float method, a fusion method, and a slot down-draw method.

A shape of the support substrate (a shape of a main surface thereof) is not particularly limited, but a rectangular shape is preferred.

The support substrate is preferably not flexible. Therefore, a thickness of the support substrate is preferably 0.3 mm or more, and more preferably 0.5 mm or more.

On the other hand, the thickness of the support substrate is preferably 1.0 mm or less.

### (Adhesion Layer)

The adhesion layer is disposed between the support substrate and the polyimide layer, and is a layer for preventing peeling of the polyimide layer disposed thereon. That is, the adhesion layer is a layer for ensuring adhesion between the support substrate and the polyimide layer.

The adhesion layer may be an organic layer or an inorganic layer.

Examples of a material of the organic layer include an acrylic resin, a polyolefin resin, a polyurethane resin, a polyimide resin, a silicone resin, a polyimide silicone resin, and a fluorine resin. The adhesion layer may also be formed by mixing several types of resins.

Examples of a material of the inorganic layer include an oxide, a nitride, an oxynitride, a carbide, a carbonitride, a silicide, a fluoride, and a metal (including a semi-metal). Examples of the oxide (preferably a metal oxide), the nitride (preferably a metal nitride), and the oxynitride (preferably a metal oxynitride) include an oxide, a nitride, and an oxynitride of one or more elements selected from Si, Hf, Zr, Ta, Ti, Y, Nb, Na, Co, Al, Zn, Pb, Mg, Bi, La, Ce, Pr, Sm, Eu, Gd, Dy, Er, Sr, Sn, In, and Ba. Among these, a nitride containing Si (a silicon atom) (for example, a silicon nitride) or an oxide containing Si (for example, a silicon oxide) is preferred.

Examples of the carbide (preferably a metal carbide) and the carbonitride (preferably a metal carbonitride) include a carbide and a carbonitride of one or more elements selected from Ti, W, Si, Zr, and Nb.

Examples of the silicide (preferably a metal silicide) include a silicide of one or more elements selected from Mo, W, and Cr.

Examples of the fluoride (preferably a metal fluoride) include a fluoride of one or more elements selected from Mg, Y, La, and Ba.

The adhesion layer may be a plasma-polymerized film.

When the adhesion layer is a plasma-polymerized film, examples of a material forming the plasma-polymerized film include a fluorocarbon monomer such as CF₄, CHF₃, C₂F₆, C₃F₆, C₂F₂, CH₃F, and CIF's; a hydrocarbon monomer such as methane, ethane, propane, ethylene, propylene, acetylene, benzene, and toluene; hydrogen; and SF₆.

The adhesion layer may be an amorphous silicon layer.

Among these, from viewpoints of heat resistance and a peeling property, a silicone resin and a polyimide silicone resin are preferred, a silicone resin is more preferred, and a silicone resin formed from a condensation-curable silicone is still more preferred as the material of the adhesion layer.

Hereinafter, a mode in which the adhesion layer is a silicone resin layer will be described in detail.

The silicone resin is a resin containing a predetermined organosiloxy unit, and is usually obtained by curing a curable silicone. The curable silicone is classified into an addition-curable silicone, a condensation-curable silicone, an ultraviolet-curable silicone, and an electron beam-curable silicone according to curing mechanisms thereof, and any one of the curable silicones may be used. Among these, a condensation-curable silicone is preferred.

As the condensation-curable silicone, a hydrolyzable organosilane compound as a monomer or a mixture thereof (a monomer mixture), or a partially hydrolyzed-condensate (organopolysiloxane) obtained by a partial hydrolysis and condensation reaction of a monomer or a monomer mixture may be suitably used.

The silicone resin can be formed by proceeding a hydrolysis and condensation reaction (a sol-gel reaction) using the condensation-curable silicone.

The adhesion layer is preferably formed using a curable composition containing a curable silicone. The curable composition may contain, in addition to the curable silicone, a solvent, a platinum catalyst (in a case where an addition-reactive silicone is used as the curable silicone), a leveling agent, a metal compound, and the like. Examples of a metal element contained in the metal compound include a 3d transition metal, a 4d transition metal, a lanthanoid metal, bismuth (Bi), aluminum (Al), and tin (Sn). A content of the metal compound is not particularly limited, and is appropriately adjusted.

An average thickness of the adhesion layer is not particularly limited, and when the adhesion layer is an organic layer, the average thickness is preferably 50.0 μm or less, more preferably 30.0 μm or less, and still more preferably 12.0 μm or less. On the other hand, when the adhesion layer is the organic layer, the average thickness of the adhesion layer is preferably 1 μm or more, and more preferably 6.0 μm or more.

When the adhesion layer is an inorganic layer, the average thickness is preferably 1000 nm or less, more preferably 500 nm or less, and still more preferably 200 nm or less. On the other hand, when the adhesion layer is the inorganic layer, the average thickness of the adhesion layer is preferably 5 nm or more, and more preferably 10 nm or more.

The average thickness is determined by measuring thicknesses at any 10 points in the adhesion layer and arithmetically averaging the thicknesses.

### (Polyimide Layer)

The polyimide layer is disposed on the adhesion layer, and is peeled off from the adhesion layer at a time of a peeling treatment to be described later. The polyimide layer is a member constituting a part of an electronic device to be described later.

The polyimide layer is a layer containing polyimide. The polyimide is usually obtained by polycondensing a tetracarboxylic acid dianhydride and a diamine, and performing imidization. More specifically, the polyimide preferably contains a repeating unit having a residue (X) of tetracarboxylic acids and a residue (A) of diamines, as represented by the following formula (1).

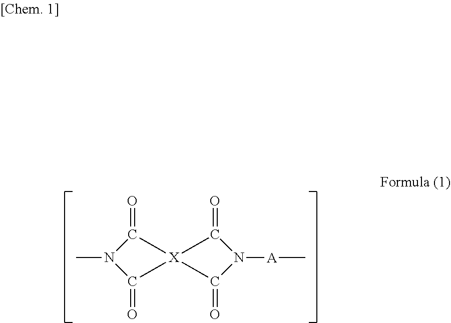

In the formula (1), X represents a tetracarboxylic acid residue obtained by removing a carboxy group from tetracarboxylic acids, and A represents a diamine residue obtained by removing an amino group from diamines.

Examples of the tetracarboxylic acid dianhydride to be used include an aromatic tetracarboxylic acid dianhydride and an aliphatic tetracarboxylic acid dianhydride. Examples of the diamine to be used include an aromatic diamine and an aliphatic diamine.

Examples of the aromatic tetracarboxylic acid dianhydride include pyromellitic anhydride (1,2,4,5-benzene tetracarboxylic acid dianhydride), 3,3′, 4,4′-benzophenone tetracarboxylic acid dianhydride, 3,3′, 4,4′-biphenyl tetracarboxylic acid dianhydride, and 3,3′, 4,4′-diphenylether tetracarboxylic acid dianhydride.

Examples of the aliphatic tetracarboxylic acid dianhydride include a cyclic or acyclic aliphatic tetracarboxylic acid dianhydride. Examples of the cyclic aliphatic tetracarboxylic acid dianhydride include a 1,2,3,4-cyclobutanetetracarboxylic acid dianhydride, a 1,2,4,5-cyclohexanetetracarboxylic acid dianhydride, and a 1,2,4,5-cyclopentanetetracarboxylic acid dianhydride. Examples of the acyclic aliphatic tetracarboxylic acid dianhydride include a 1,2,3,4-butanetetracarboxylic acid dianhydride and a 1,2,3,4-pentanetetracarboxylic acid dianhydride.

Examples of the aromatic diamine include 4,4′-oxydiaminobenzene (4,4′-diaminodiphenyl ether), 1,3-bis(3-amino phenoxy)benzene, 4,4′-bis(3-amino phenoxy)biphenyl, 1,4-diaminobenzene, and 1,3-diaminobenzene.

Examples of the aliphatic diamine include an acyclic aliphatic diamine such as ethylene diamine, hexamethylene diamine, polyethylene glycol bis(3-amino propyl)ether, and polypropylene glycol bis(3-amino propyl)ether, and a cyclic aliphatic diamine such as 1,3-bis(amino methyl)cyclohexane, 1,4-bis(amino methyl)cyclohexane, isophorone diamine, and norbornanediamine.

An average thickness of the polyimide layer is preferably 1 μm or more, and more preferably 5 μm or more. From a viewpoint of flexibility, the average thickness is preferably 1 mm or less, and more preferably 0.2 mm or less.

The average thickness is determined by measuring thicknesses at any 10 points in the polyimide layer and arithmetically averaging the thicknesses.

### (Inorganic Layer)

The inorganic layer is a layer disposed on the polyimide layer. The inorganic layer preferably functions as a so-called gas barrier layer.

A material constituting the inorganic layer is not particularly limited, and examples thereof include an oxide, a nitride, an oxynitride, a carbide, a carbonitride, a silicide, and a fluoride. Examples of the oxide (preferably a metal oxide), the nitride (preferably a metal nitride), and the oxynitride (preferably a metal oxynitride) include an oxide, a nitride, and an oxynitride of one or more elements selected from Si, Hf, Zr, Ta, Ti, Y, Nb, Na, Co, Al, Zn, Pb, Mg, Bi, La, Ce, Pr, Sm, Eu, Gd, Dy, Er, Sr, Sn, In, and Ba. More specifically, examples thereof include silicon nitride (SiN), Al₂O₃, SiO₂, and SiON. Among these, a nitride containing Si (for example, a silicon nitride) or an oxide containing Si (for example, a silicon oxide) is preferred.

An average thickness of the inorganic layer is preferably 10 nm to 5000 nm, and more preferably 50 nm to 1000 nm.

### <Method for Manufacturing Laminate>

A method for manufacturing the laminate is not particularly limited, and examples thereof include known methods.

For example, a method of forming an adhesion layer in a predetermined region on a support substrate, then forming a polyimide layer on the adhesion layer, and forming an inorganic layer on the polyimide layer may be used.

Hereinafter, a manufacturing procedure for each layer will be described in detail.

First, the adhesion layer is formed in the predetermined region on the support substrate.

As a method for forming the adhesion layer, an optimum method is appropriately selected depending on a material of the adhesion layer. For example, when a silicone resin layer is formed as the adhesion layer, a method of coating the predetermined region on the support substrate with the curable composition containing the curable silicone described above, and subjecting a coating film to a heat treatment may be used.

When an inorganic layer is formed as the adhesion layer, methods of plasma CVD and sputtering may be used.

Among these, in a case where the silicone resin layer is used as the adhesion layer, when productivity is excellent, a method may be used of preparing a transfer film including a temporary support and a precursor film that is disposed on the temporary support and becomes the silicone resin layer after a heat treatment, bonding the precursor film in the transfer film to a predetermined position on the support substrate, and subjecting an obtained laminate including the support substrate, the precursor film, and the temporary support to the heat treatment. The silicone resin layer is formed by the heat treatment.

Hereinafter, the above procedure will be described in detail.

In the above, first, the transfer film including the temporary support and the precursor film that becomes the silicone resin layer after the heat treatment is prepared, and the precursor film in the transfer film is bonded to the predetermined position on the support substrate.

After the transfer film is bonded to the support substrate, the obtained laminate may be washed with an alkaline detergent. After washing with an alkaline detergent, the laminate may be rinsed with pure water as necessary. Further, after rinsing with pure water, the laminate may be drained with an air knife as necessary.

The heat treatment for forming the silicone resin layer is preferably performed while applying a pressure. Specifically, the heat treatment and a pressure treatment are preferably performed using an autoclave.

A heating temperature at the time of the heat treatment is preferably 50° C. to 350° C., more preferably 55° C. to 300° C., and still more preferably 60° C. to 250° C. A heating time is preferably 10 minutes to 60 minutes, and more preferably 20 minutes to 40 minutes.

A pressure at the time of the pressure treatment is preferably 0.5 MPa to 1.5 MPa, and more preferably 0.8 MPa to 1.0 MPa.

The heat treatment may be performed a plurality of times. When the heat treatment is performed a plurality of times, heating conditions for each time may be changed.

Next, a predetermined position on an adhesion layer side of the obtained support substrate is coated with a polyimide varnish containing polyimide or a precursor thereof and a solvent to form the polyimide layer.

The polyimide varnish contains polyimide or a precursor thereof and a solvent.

The polyimide is usually obtained by polycondensing a tetracarboxylic acid dianhydride and a diamine, and performing imidization. The polyimide preferably has solvent solubility.

The tetracarboxylic acid dianhydride and the diamine to be used are desirably to have an aromatic group in consideration of mechanical properties after being formed into a film.

Specific examples of the tetracarboxylic acid dianhydride and the diamine include compounds exemplified for the polyimide layer.

The precursor of the polyimide means polyamide acid (so-called polyamic acid and/or polyamic acid ester) in a state before imidization.

The solvent may be any solvent that dissolves a polyimide or a precursor thereof, and examples thereof include a phenol-based solvent (for example, m-cresol), an amide-based solvent (for example, N-methyl-2-pyrrolidone, N,N-dimethylformamide, and N,N-dimethylacetamide), a lactone-based solvent (for example, γ-butyrolactone, δ-valerolactone, ε-caprolactone, γ-crotonolactone, γ-hexanolactone, α-methyl-γ-butyrolactone, γ-valerolactone, α-acetyl-γ-butyrolactone, and δ-hexanolactone), a sulfoxide-based solvent (for example, dimethylsulfoxide), a ketone-based solvent (for example, acetone, methyl ethyl ketone, methyl isobutyl ketone, and cyclohexanone), and an ester-based solvent (for example, methyl acetate, ethyl acetate, butyl acetate, and dimethyl carbonate).

A method of coating with the polyimide varnish is not particularly limited, and examples thereof include known methods. For example, a spray coating method, a die coating method, a spin coating method, a dip coating method, a roll coating method, a bar coating method, a screen printing method, or a gravure coating method may be used.

After the coating, a heat treatment may be performed as necessary.

As conditions for the heat treatment, a temperature condition is preferably 50° C. to 500° C., and more preferably 50° C. to 450° C. A heating time is preferably 10 minutes to 300 minutes, and more preferably 20 minutes to 200 minutes.

The heat treatment may be performed a plurality of times. When the heat treatment is performed a plurality of times, heating conditions for each time may be changed.

Thereafter, the inorganic layer is formed at a predetermined position on the polyimide layer.

A method for forming the inorganic layer is not particularly limited, and examples thereof include methods of plasma CVD and sputtering.

The laminate may be used for various applications, and examples of the applications include manufacture of electronic components to be described later such as a display device panel, a PV, a thin film secondary battery, a semiconductor wafer including a circuit formed on a surface thereof, and a receiving sensor panel. In such applications, the laminate may be exposed (for example, 20 minutes or more) to a high temperature condition (for example, 450° C. or higher) in an air atmosphere.

The display device panel includes an LCD, an OLED, an electronic paper, a plasma display panel, a field emission panel, a quantum dot LED panel, a micro LED display panel, a MEMS shutter panel, and the like.

Examples of the receiving sensor panel includes an electromagnetic wave receiving sensor panel, an X-ray receiving sensor panel, an ultraviolet ray receiving sensor panel, a visible light receiving sensor panel, an infrared ray receiving sensor panel, and the like. A substrate used for the receiving sensor panel may be reinforced with, for example, a reinforcing sheet made of a resin or the like.

### <Method for Manufacturing Electronic Device>

An electronic device including the polyimide layer, the inorganic layer, and a member for electronic device to be described later is manufactured using the laminate.

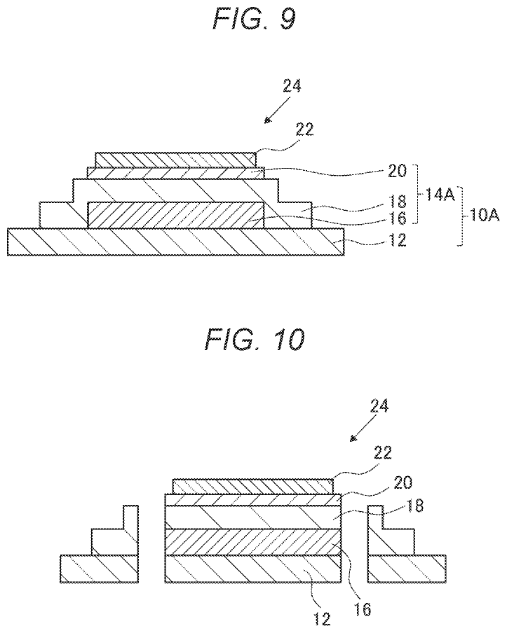

When the laminate 10A is used, for example, as shown in FIGS. 9 to 11, a method for manufacturing an electronic device includes a member forming step of forming a member for electronic device 22 on the inorganic layer 20 of the laminate 10A to obtain a laminate with a member for electronic device 24, a cutting step of cutting a part of the laminate with a member for electronic device 24, and a separation step of obtaining an electronic device 26 including the polyimide layer 18, the inorganic layer 20, and the member for electronic device 22 from the laminate with a member for electronic device 24.

Hereinafter, a step of forming the member for electronic device 22 is referred to as the “member forming step”, a step of cutting a part of the laminate with a member for electronic device 24 is referred to as the “cutting step”, and a step of separating the laminate with a member for electronic device 24 into the electronic device 26 and an adhesion layer-attached support substrate is referred to as the “separation step”.

Hereinafter, materials and procedures used in each step will be described in detail.

### (Member Forming Step)

The member forming step is a step of forming the member for electronic device 22 on the inorganic layer 20 of the laminate 10A. More specifically, as shown in FIG. 9, the member for electronic device 22 is formed on the inorganic layer 20 to obtain the laminate with a member for electronic device 24.

First, the member for electronic device 22 used in this step will be described in detail, and then step procedures will be described in detail.

### (Member For Electronic Device)

The member for electronic device 22 is a member constituting at least a part of an electronic device formed on the inorganic layer 20 of the laminate 10A. More specifically, examples of the member for electronic device 22 include an electronic component such as a display device panel, a solar cell, a thin film secondary battery, or a semiconductor wafer including a circuit formed on a surface thereof, and a member used for a receiving sensor panel or the like (for example, a display device member such as low temperature polysilicon (UPS), a solar cell member, a thin film secondary battery member, an electronic component circuit, and a receiving sensor member), and examples thereof include a solar cell member described in paragraph 0192, a thin film secondary battery member described in paragraph 0193, and an electronic component circuit described in paragraph 0194 of US Patent Application Publication No. 2018/0178492.

### (Step Procedure)

A method for manufacturing the laminate with a member for electronic device 24 is not particularly limited, and the member for electronic device 22 is formed on the inorganic layer 20 of the laminate 10A by a method known in related art depending on a type of a constituent member of the member for electronic device.

Instead of an entire member finally formed on the inorganic layer 20 (hereinafter, referred to as an “entire member”), the member for electronic device 22 may be a part of the entire member (hereinafter, referred to as a “partial member”). A partial member-attached substrate peeled off from the adhesion layer 16 may be used to manufacture an entire member-attached substrate (corresponding to an electronic device to be described later) in subsequent steps.

Another member for electronic device may be formed on a peeling surface of the entire member-attached substrate peeled off from the adhesion layer 16. Further, the electronic device may also be manufactured by making the members for electronic device 22 of the two laminates with a member for electronic device 24 face each other and bonding the members for electronic device 22 to each other to assemble an entire member-attached laminate, and then peeling the two adhesion layer-attached support substrates from the entire member-attached laminate.

For example, in a case of manufacturing an organic light emitting diode (OLED), in order to form an organic EL structure on the inorganic layer 20 of the laminate 10A, various layer formations and treatments are performed, such as forming a transparent electrode, further depositing a hole injection layer, a hole transport layer, a light emitting layer, an electron transport layer, and the like on a surface on which the transparent electrode is formed, forming a back electrode, and sealing using a sealing plate. Specific examples of these layer formations and treatments include a film formation treatment, a deposition treatment, and an adhesion treatment of a sealing plate.

### (Cutting Step)

As shown in FIG. 10, the cutting step is a step of cutting a part of the laminate with a member for electronic device 24 obtained in the member forming step.

A cutting method is not particularly limited, and examples thereof include a method of cutting with a laser beam and a method of cutting with a cutting machine such as a dicing saw.

### (Separation Step)

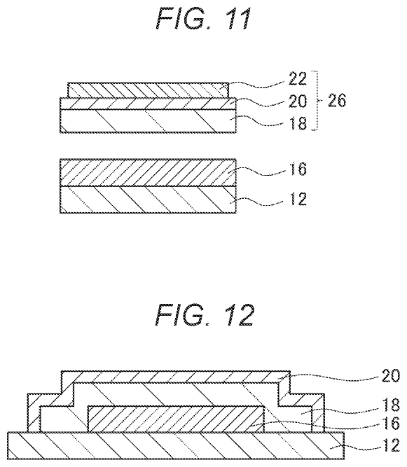

As shown in FIG. 11, the separation step is a step of obtaining the electronic device 26 including the member for electronic device 22, the inorganic layer 20, and the polyimide layer 18 by separating the laminate with a member for electronic device 24 obtained in the cutting step into the adhesion layer 16—attached support substrate 12 and the polyimide layer 18 on which the member for electronic device 22 is laminated, with an interface between the adhesion layer 16 and the polyimide layer 18 as a peeling surface.

When the member for electronic device 22 on the peeled inorganic layer 20 is a part of formation of all necessary constituent members, remaining constituent members may be further formed after the separation.

A method for peeling the polyimide layer 18 and the adhesion layer 16 is not particularly limited. For example, the peeling can be performed by inserting a sharp blade-shaped object in the interface between the polyimide layer 18 and the adhesion layer 16 to give a trigger of peeling, and then blowing a mixed fluid of water and compressed air. A laser lift-off method may be used.

Preferably, the laminate with a member for electronic device 24 is placed on a surface plate such that the support substrate 12 side is at an upper side and an electronic device member 22 side is at a lower side, the member for electronic device 22 side is vacuum-suctioned on the surface plate, and in this state, first, a blade-shaped object is inserted into the interface between the polyimide layer 18 and the adhesion layer 16. Thereafter, the support substrate 12 side is suctioned by a plurality of vacuum suction pads, and the vacuum suction pads are sequentially raised from a vicinity of a portion where the blade-shaped object is inserted. Thus, the adhesion layer 16—attached support substrate 12 (see FIG. 11) can be easily peeled off.

At the time of peeling the polyimide layer 18 and the adhesion layer 16, in a case where the member for electronic device 22 is produced for each of a plurality of cells, after cutting the laminate with a member for electronic device 24 for each cell, the polyimide layer 18 and the adhesion layer 16 may be peeled for each cut cell. Examples of a method of cutting for each cell include a method of cutting with a laser beam and a method of cutting with a cutting machine such as a dicing saw.

At the time of separating the electronic device 26 from the laminate with a member for electronic device 24, electrostatic suction of fragments of the adhesion layer 16 to the electronic device 26 can be further prevented by spraying with an ionizer or controlling humidity.

The above method for manufacturing an electronic device is suitable for, for example, manufacturing a display device described in paragraph 0210 of US Patent Application Publication No. 2018/0178492, and examples of the electronic device 26 include those components described in paragraph 0211 of the same literature.

A protective film may be bonded to a surface, opposite to a polyimide layer 18 side, of the member for electronic device 22 of the separated electronic device 26.

### EXAMPLES

Hereinafter, the present invention will be specifically described with reference to Examples and the like, but the present invention is not limited to these examples.

Hereinafter, as a support substrate, a glass substrate made of an alkali-free borosilicate glass (linear expansion coefficient: 39×10⁻⁷/° C., trade name “AN Wizus” (registered trademark) manufactured by AGC Inc., thickness: 0.5 mm, size: 470 mm×370 mm) was used.

Hereinafter, Examples 1 to 10 are Working Examples, and Examples 11 to 16 are Comparative Examples.

### (Preparation of Curable Silicone 1)

A curable silicone 1 was obtained by mixing an organohydrogensiloxane and an alkenyl group-containing siloxane. A composition of the curable silicone 1 was such that a molar ratio of M units, D units, and T units was 9:59:32, a molar ratio of a methyl group and a phenyl group in an organic group was 44:56, a molar ratio of all hydrogen atoms bonded to a silicon atom to all alkenyl groups (hydrogen atom/alkenyl group) was 0.7, and an average number of OX groups was 0.1.

### (Preparation of Curable Composition 1)

Platinum(0)-1, 3-divinyl-1, 1,3,3-tetramethyldisiloxane (CAS No. 68478-92-2) was added to the curable silicone 1 such that a platinum element content was 120 ppm, thereby obtaining a mixture A. The mixture A (200 g) was mixed with diethylene glycol diethyl ether (“HISOLVE EDE”, manufactured by Toho Chemical Industry Co., Ltd.) (84.7 g) as a solvent, and an obtained mixed solution was filtered using a filter having a pore diameter of 0.45 μm to obtain a curable composition 1.

The curable composition 1 corresponds to an addition-curable silicone composition.

### (Preparation of Curable Silicone 2)

Triethoxymethylsilane (179 g), toluene (300 g), and acetic acid (5 g) were added to a 1 L flask, and the mixture was stirred at 25° C. for 20 minutes, then heated to 60° C., and reacted for 12 hours. An obtained crude reaction solution was cooled to 25° C., and then washed with water (300 g) three times. Chlorotrimethylsilane (70 g) was added to the washed crude reaction solution, and the mixture was stirred at 25° C. for 20 minutes, then heated to 50° C., and reacted for 12 hours. An obtained crude reaction solution was cooled to 25° C., and then washed with water (300 g) three times. Toluene was evaporated from the washed crude reaction solution under reduced pressure to form a slurry, which was dried overnight in a vacuum dryer to obtain a curable silicone 2 which is a white organopolysiloxane compound. In the curable silicone 2, the number of T units: the number of M units=87:13 (molar ratio). In the curable silicone 2, a molar ratio of M units and T units was 13:87, all organic groups were methyl groups, and an average number of OX groups was 0.02. The average number of OX groups is a numerical value representing an average number of OX groups (X is a hydrogen atom or a hydrocarbon group) bonded to one Si atom. The M unit means a monofunctional organosiloxy unit represented by (R)₃SiO_{1/2}. The T unit means a trifunctional organosiloxy unit represented by RSiO_{3/2} (R represents a hydrogen atom or an organic group).

### (Preparation of Curable Composition 2)

The curable silicone 2 (20 g), a zirconium octoate compound (“ORGATIX ZC-200”, manufactured by Matsumoto Fine Chemical Co., Ltd.) (0.16 g) and cerium (III) 2-ethylhexanoate (manufactured by Alfa Aesar, metal content: 12%) (0.17 g) as metal compounds, and Isoper G (manufactured by TonenGeneral Sekiyu K.K.) (19.7 g) as a solvent were mixed, and an obtained mixed solution was filtered using a filter having a pore diameter of 0.45 μm to obtain a curable composition 2.

The curable composition 2 corresponds to a condensation-curable silicone composition.

### Example 1

### (Formation of Silicone Resin Layer)

A glass substrate as a support substrate was washed with a water-based glass detergent (“PK-LCG 213” manufactured by Parker Corporation) and then washed with pure water.

Next, a predetermined position on the glass substrate was coated with the curable composition 1 using a slit coater. After heating at 120° C. for 10 minutes using a hot plate, heating was performed at 250° C. for 30 minutes in an air atmosphere using a clean oven to form a silicone resin layer (thickness: 6.5 μm). A formation area of the silicone resin layer was as shown in Table 1 to be described later.

### (Formation of Polyimide Layer)

The silicone resin layer obtained above was subjected to a corona treatment, then coated with a colorless polyimide varnish (“Neopulim H230” manufactured by Mitsubishi Gas Chemical Company, Inc.), and heated at 80° C. for 20 minutes using a hot plate. Subsequently, heating was performed at 400° C. for 30 minutes in a nitrogen atmosphere using an inert gas oven (a curing step) to produce a laminate including the glass substrate, the silicone resin layer, and a polyimide layer (thickness: 7 μm) in this order. A formation area of the polyimide layer was as shown in Table 1 to be described later, and as shown in FIGS. 4 and 5, an outer edge of the polyimide layer was located outside an outer edge of the silicone resin layer.

### (Formation of Inorganic Layer)

A silicon nitride layer having a thickness of 100 nm was formed, using a plasma CVD apparatus, on a surface of the polyimide layer obtained above to produce a laminate 1 including the glass substrate, the silicone resin layer, the polyimide layer, and an inorganic layer in this order. A formation area of the inorganic layer was as shown in Table 1 to be described later, and as shown in FIGS. 4 and 5, an outer edge of the inorganic layer was located inside the outer edge of the silicone resin layer.

When the laminate 1 was observed from a normal direction of a surface of the laminate 1, a center of gravity of the silicone resin layer, a center of gravity of the polyimide layer, and a center of gravity of the inorganic layer coincided with each other.

### Example 2

A laminate 2 was produced by the same procedure as in Example 1 except that the curable composition 2 was used instead of the curable composition 1, and heating conditions at the time of forming a silicone resin layer were changed to heating at 120° C. for 10 minutes and then heating at 300° C. for 30 minutes in an air atmosphere using a clean oven.

### Example 3

A laminate 3 was produced by the same procedure as in Example 1 except that a procedure of (Formation of Silicon Oxide Layer) to be described later was performed instead of (Formation of Silicone Resin Layer).

### (Formation of Silicon Oxide Layer)

A glass substrate as a support substrate was washed with a water-based glass detergent (“PK-LCG 213” manufactured by Parker Corporation) and then washed with pure water.

Next, a silicon oxide layer having a thickness of 100 nm was formed at a predetermined position on the glass substrate using a plasma CVD apparatus. A formation area of the silicon oxide layer was as shown in Table 1 to be described later.

### Example 4

A laminate 4 was produced by the same procedure as in Example 1 except that a procedure of (Formation of Silicon Nitride Layer) to be described later was performed instead of (Formation of Silicone Resin Layer).

### (Formation of Silicon Nitride Layer)

A glass substrate as a support substrate was washed with a water-based glass detergent (“PK-LCG 213” manufactured by Parker Corporation) and then washed with pure water.

Next, a silicon nitride layer having a thickness of 100 nm was formed at a predetermined position on the glass substrate using a plasma CVD apparatus. A formation area of the silicon nitride layer was as shown in Table 1 to be described later.

### Example 5

A laminate 5 was produced by the same procedure as in Example 1 except that a procedure of (Formation of Amorphous Silicon Layer) to be described later was performed instead of (Formation of Silicone Resin Layer).

### (Formation of Amorphous Silicon Layer)

A glass substrate as a support substrate was washed with a water-based glass detergent (“PK-LCG 213” manufactured by Parker Corporation) and then washed with pure water.

Next, an amorphous silicon layer having a thickness of 50 nm was formed at a predetermined position on the glass substrate using a plasma CVD apparatus. A formation area of the amorphous silicon layer was as shown in Table 1 to be described later.

### Example 6

A laminate 6 was produced by the same procedure as in Example 1 except that in (Formation of Inorganic Layer), an inorganic layer was formed such that an outer edge of the inorganic layer coincided with an outer edge of a silicone resin layer as shown in FIGS. 2 and 3.

### Example 7

A laminate 7 was produced by the same procedure as in Example 2 except that in (Formation of Inorganic Layer), an inorganic layer was formed such that an outer edge of the inorganic layer coincided with an outer edge of a silicone resin layer as shown in FIGS. 2 and 3.

### Example 8

A laminate 8 was produced by the same procedure as in Example 3 except that in (Formation of Inorganic Layer), an inorganic layer was formed such that an outer edge of the inorganic layer coincided with an outer edge of a silicone resin layer as shown in FIGS. 2 and 3.

### Example 9

A laminate 9 was produced by the same procedure as in Example 4 except that in (Formation of Inorganic Layer), an inorganic layer was formed such that an outer edge of the inorganic layer coincided with an outer edge of a silicone resin layer as shown in FIGS. 2 and 3.

### Example 10

A laminate 10 was produced by the same procedure as in Example 5 except that in (Formation of Inorganic Layer), an inorganic layer was formed such that an outer edge of the inorganic layer coincided with an outer edge of a silicone resin layer as shown in FIGS. 2 and 3.

### Example 11

A laminate 11 was produced by the same procedure as in Example 2 except that in (Formation of Inorganic Layer), a formation area of an inorganic layer was changed to that shown in Table 1 to be described later.

As shown in FIG. 12, the laminate 11 had a configuration including the support substrate 12, the adhesion layer 16 (corresponding to a silicone resin layer), the polyimide layer 18, and the inorganic layer 20 in this order, and when the laminate 11 was observed from a normal direction of a surface of the laminate 11, an outer edge of the polyimide layer 18 was located outside an outer edge of the adhesion layer 16, and an outer edge of the inorganic layer 20 was located outside the outer edge of the polyimide layer 18.

When the laminate 11 was observed from the normal direction of the surface of the laminate 11, a center of gravity of the silicone resin layer, a center of gravity of a polyimide layer, and a center of gravity of the inorganic layer coincided with each other.

### Example 12

A laminate 12 was produced by the same procedure as in Example 4 except that in (Formation of Inorganic Layer), a formation area of an inorganic layer was changed to that shown in Table 1 to be described later.

As shown in FIG. 12, the laminate 12 had a configuration including the support substrate 12, the adhesion layer 16 (corresponding to a silicon nitride layer), the polyimide layer 18, and the inorganic layer 20 in this order, and when the laminate 12 was observed from a normal direction of a surface of the laminate 12, an outer edge of the polyimide layer 18 was located outside an outer edge of the adhesion layer 16, and an outer edge of the inorganic layer 20 was located outside the outer edge of the polyimide layer 18.

When the laminate 12 was observed from the normal direction of the surface of the laminate 12, a center of gravity of the silicon nitride layer, a center of gravity of a polyimide layer, and a center of gravity of the inorganic layer coincided with each other.

### Example 13

A laminate 13 was produced by the same procedure as in Example 2 except that in (Formation of Inorganic Layer), a formation area of an inorganic layer was changed to that shown in Table 1 to be described later.

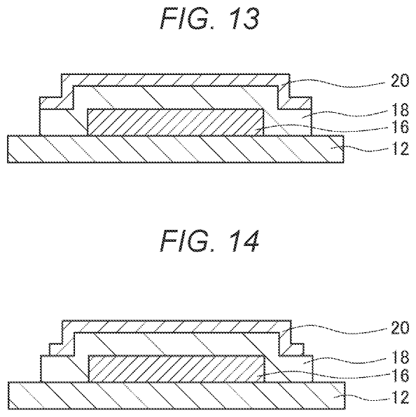

As shown in FIG. 13, the laminate 13 had a configuration including the support substrate 12, the adhesion layer 16 (corresponding to a silicone resin layer), the polyimide layer 18, and the inorganic layer 20 in this order, and when the laminate 13 was observed from a normal direction of a surface of the laminate 13, an outer edge of the polyimide layer 18 was located outside an outer edge of the adhesion layer 16, and an outer edge of the inorganic layer 20 and the outer edge of the polyimide layer 18 coincided with each other.

When the laminate 13 was observed from the normal direction of the surface of the laminate 13, a center of gravity of the silicone resin layer, a center of gravity of a polyimide layer, and a center of gravity of the inorganic layer coincided with each other.

### Example 14

A laminate 14 was produced by the same procedure as in Example 4 except that in (Formation of Inorganic Layer), a formation area of an inorganic layer was changed to that shown in Table 1 to be described later.

As shown in FIG. 13, the laminate 14 had a configuration including the support substrate 12, the adhesion layer 16 (corresponding to a silicon nitride layer), the polyimide layer 18, and the inorganic layer 20 in this order, and when the laminate 14 was observed from a normal direction of a surface of the laminate 14, an outer edge of the polyimide layer 18 was located outside an outer edge of the adhesion layer 16, and an outer edge of the inorganic layer 20 and the outer edge of the polyimide layer 18 coincided with each other.

When the laminate 14 was observed from the normal direction of the surface of the laminate 14, a center of gravity of the silicon nitride layer, a center of gravity of a polyimide layer, and a center of gravity of the inorganic layer coincided with each other.

### Example 15

A laminate 15 was produced by the same procedure as in Example 2 except that in (Formation of Inorganic Layer), a formation area of an inorganic layer was changed to that shown in Table 1 to be described later.

As shown in FIG. 14, the laminate 15 had a configuration including the support substrate 12, the adhesion layer 16 (corresponding to a silicone resin layer), the polyimide layer 18, and the inorganic layer 20 in this order, and when the laminate 15 was observed from a normal direction of a surface of the laminate 15, an outer edge of the polyimide layer 18 was located outside an outer edge of the adhesion layer 16, and an outer edge of the inorganic layer 20 was located inside the outer edge of the polyimide layer 18 and outside the outer edge of the adhesion layer 16.

When the laminate 15 was observed from the normal direction of the surface of the laminate 15, a center of gravity of the silicone resin layer, a center of gravity of a polyimide layer, and a center of gravity of the inorganic layer coincided with each other.

### Example 16

A laminate 16 was produced by the same procedure as in Example 4 except that in (Formation of Inorganic Layer), a formation area of an inorganic layer was changed to that shown in Table 1 to be described later.

As shown in FIG. 14, the laminate 16 had a configuration including the support substrate 12, the adhesion layer 16 (corresponding to a silicon nitride layer), the polyimide layer 18, and the inorganic layer 20 in this order, and when the laminate 16 was observed from a normal direction of a surface of the laminate 16, an outer edge of the polyimide layer 18 was located outside an outer edge of the adhesion layer 16, and an outer edge of the inorganic layer 20 was located inside the outer edge of the polyimide layer 18 and outside the outer edge of the adhesion layer 16.

When the laminate 16 was observed from the normal direction of the surface of the laminate 16, a center of gravity of the silicon nitride layer, a center of gravity of a polyimide layer, and a center of gravity of the inorganic layer coincided with each other.

### <Heat Resistance Evaluation>

A heat resistance test was performed by heating the laminate produced in each example at 380° C. for 1 hour in a nitrogen atmosphere. An appearance of the laminate after the heat resistance test was visually confirmed to evaluate whether foaming and cracking occurred in the polyimide layer. A case where neither foaming nor cracking occurred was evaluated as “No”, and a case where at least one of foaming and cracking occurred was evaluated as “Yes”.

The same evaluation as above was performed by changing a temperature of 380° C. to 400° C. or 420° C.

In Table 1, a column “size relationship of outer edges of layers” shows a positional relationship of the outer edges of the layers when the laminate of each example is observed from the normal direction of the surface thereof, “=” means that outer edges of two layers coincide with each other, and “A>B” means that an outer edge of A is located outside an outer edge of B. “PI” means the polyimide layer. For example, “PI>adhesion layer=inorganic layer” in Example 1 means that the outer edge of the polyimide layer is located outside the outer edge of the adhesion layer and the outer edge of the adhesion layer and the outer edge of the inorganic layer coincide with each other.

In Table 1, a column “laminate configuration” shows a drawing illustrating an arrangement relationship of the layers in the laminate. For example, the laminate of Example 1 has the configuration of the laminate shown in FIGS. 4 and 5 described above.

TABLE 1

| | | Formation area of each layer | | | Size relationship of |
|---|---|---|---|---|---|
| | Adhesion | Adhesion | Polyimide | Inorganic | outer edges |
| | layer | layer | layer | layer | of layers |
| EX. 1 | Addition-curable | 440 × 340 | 450 × 350 | 430 × 330 | PI > adhesion layer > |
| | silicone resin | mm | mm | mm | inorganic layer |
| | layer | | | | |
| EX. 2 | Condensation- | 440 × 340 | 450 × 350 | 430 × 330 | PI > adhesion layer > |
| | curable silicone | mm | mm | mm | inorganic layer |
| | resin layer | | | | |
| EX. 3 | Silicon oxide layer | 440 × 340 | 450 × 350 | 430 × 330 | PI > adhesion layer > |
| | | mm | mm | mm | inorganic layer |
| EX. 4 | Silicon nitride | 440 × 340 | 450 × 350 | 430 × 330 | PI > adhesion layer > |
| | layer | mm | mm | mm | inorganic layer |
| EX. 5 | Amorphous | 440 × 340 | 450 × 350 | 430 × 330 | PI > adhesion layer > |
| | silicon layer | mm | mm | mm | inorganic layer |
| EX. 6 | Addition-curable | 440 × 340 | 450 × 350 | 440 × 340 | PI > adhesion layer = |
| | silicone resin | mm | mm | mm | inorganic layer |
| | layer | | | | |
| EX. 7 | Condensation- | 440 × 340 | 450 × 350 | 440 × 340 | PI > adhesion layer = |
| | curable silicone | mm | mm | mm | inorganic layer |
| | resin layer | | | | |
| EX. 8 | Silicon oxide layer | 440 × 340 | 450 × 350 | 440 × 340 | PI > adhesion layer = |
| | | mm | mm | mm | inorganic layer |
| EX. 9 | Silicon nitride | 440 × 340 | 450 × 350 | 440 × 340 | PI > adhesion layer = |
| | layer | mm | mm | mm | inorganic layer |
| EX. 10 | Amorphous | 440 × 340 | 450 × 350 | 440 × 340 | PI > adhesion layer = |
| | silicon layer | mm | mm | mm | inorganic layer |
| EX. 11 | Condensation- | 440 × 340 | 450 × 350 | 460 × 360 | Inorganic layer > PI > |
| | curable silicone | mm | mm | mm | adhesion layer |
| | resin layer | | | | |
| EX. 12 | Silicon nitride | 440 × 340 | 450 × 350 | 460 × 360 | Inorganic layer > PI > |
| | layer | mm | mm | mm | adhesion layer |
| EX. 13 | Condensation- | 440 × 340 | 450 × 350 | 450 × 350 | Inorganic layer = PI > |
| | curable silicone | mm | mm | mm | adhesion layer |
| | resin layer | | | | |
| EX. 14 | Silicon nitride | 440 × 340 | 450 × 350 | 450 × 350 | Inorganic layer = PI > |
| | layer | mm | mm | mm | adhesion layer |
| EX. 15 | Condensation- | 430 × 330 | 450 × 350 | 440 × 340 | PI > inorganic layer > |
| | curable silicone | mm | mm | mm | adhesion layer |
| | resin layer | | | | |
| EX. 16 | Silicon nitride | 430 × 330 | 450 × 350 | 440 × 340 | PI > inorganic layer > |
| | layer | mm | mm | mm | adhesion layer |

| | | Evaluation result | Evaluation result | Evaluation result |
|---|---|---|---|---|
| | Laminate | of heat resistance | of heat resistance | of heat resistance |
| | configuration | test at 380° C. | test at 400° C. | test at 420° C. |
| EX. 1 | FIGS. 4 and 5 | No | No | Yes |
| EX. 2 | FIGS. 4 and 5 | No | No | No |
| EX. 3 | FIGS. 4 and 5 | No | Yes | Yes |
| EX. 4 | FIGS. 4 and 5 | No | Yes | Yes |
| EX. 5 | FIGS. 4 and 5 | No | Yes | Yes |
| EX. 6 | FIGS. 2 and 3 | No | No | Yes |
| EX. 7 | FIGS. 2 and 3 | No | No | No |
| EX. 8 | FIGS. 2 and 3 | No | Yes | Yes |
| EX. 9 | FIGS. 2 and 3 | No | Yes | Yes |
| EX. 10 | FIGS. 2 and 3 | No | Yes | Yes |
| EX. 11 | FIG. 12 | Yes | Yes | Yes |
| EX. 12 | FIG. 12 | Yes | Yes | Yes |
| EX. 13 | FIG. 13 | Yes | Yes | Yes |
| EX. 14 | FIG. 13 | Yes | Yes | Yes |
| EX. 15 | FIG. 14 | Yes | Yes | Yes |
| EX. 16 | FIG. 14 | Yes | Yes | Yes |

As shown in results of the heat resistance test at 380° C. in Examples 1 to 10, it was confirmed that the laminate of the present invention exhibited desired effects.

Among these, according to results of the heat resistance tests at 400° C. and 420° C., more excellent effects were obtained when the silicone resin layer was used as the adhesion layer, and even more excellent effects were obtained when the condensation-curable silicone resin layer was used.

In Examples 11 to 14, at least one of foaming and cracking was observed in the polyimide layer located outside the outer edge of the adhesion layer.

In Examples 15 and 16, at least one of foaming and cracking was observed in a region of the polyimide layer located outside the outer edge of the adhesion layer and inside the outer edge of the inorganic layer.

Although the present invention has been described in detail and by reference to the specific embodiments, it is apparent to one skilled in the art that various modifications or changes can be made without departing the spirit and scope of the present invention. This application is based on Japanese Patent Application (No. 2022-067597) filed on Apr. 15, 2022, the disclosure of which is incorporated herein by reference.

### REFERENCE SIGNS LIST

10A, 10B, 10C, and 10D: laminate
12: support substrate
14A, 14B, 14C: laminated portion
16: adhesion layer
18: polyimide layer
20: inorganic layer
22: member for electronic device
24: laminate with a member for electronic device
26: electronic device

What is claimed is:

1. A laminate comprising:
a support substrate; and
a laminated portion disposed on at least a partial region of the support substrate,
wherein
the laminated portion comprises an adhesion layer, a polyimide layer, and an inorganic layer in this order from a support substrate side, and
when the laminate is observed from a normal direction of a surface of the laminate,
an outer edge of the polyimide layer is located outside an outer edge of the adhesion layer, and
an outer edge of the inorganic layer coincides with the outer edge of the adhesion layer; the outer edge of the inorganic layer is located inside the outer edge of the adhesion layer; or a part of the outer edge of the inorganic layer coincides with a part of the outer edge of the adhesion layer and a remaining part of the outer edge of the inorganic layer is located inside the outer edge of the adhesion layer.

2. The laminate according to claim 1, wherein the adhesion layer is a silicone resin layer.

3. The laminate according to claim 1, wherein the inorganic layer comprises a nitride comprising Si or an oxide comprising Si.

4. The laminate according to claim 1, wherein two or more of the laminated portions are disposed on the support substrate.

5. The laminate according to claim 1, wherein the support substrate is a glass substrate.

6. A laminate with a member for electronic device, comprising:
the laminate according to claim 1; and
a member for electronic device disposed on the inorganic layer of the laminate.

7. A method for manufacturing an electronic device, the method comprising:
a member forming step of forming a member for electronic device on the inorganic layer of the laminate according to claim 1 to obtain a laminate with a member for electronic device; and
a separation step of obtaining an electronic device comprising the polyimide layer, the inorganic layer, and the member for electronic device from the laminate with a member for electronic device.
